(19) United States
(12) Patent Application Publication
(10) Pub. No.: US 2008/0295772 A1
(43) Pub. Date: Dec. 4, 2008

(54) CHEMICAL VAPOR DEPOSITION APPARATUS AND PLASMA ENHANCED CHEMICAL VAPOR DEPOSITION APPARATUS

(75) Inventors: Yong-Woo PARK, Suwon-si (KR); Kyoung-Bo Kim, Suwon-si (KR); Moo-Jin Kim, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/122,904

(22) Filed: May 19, 2008

(30) Foreign Application Priority Data
May 31, 2007 (KR) 2007-53415

(51) Int. Cl. C23C 16/44

(52) U.S. Cl. 118/723 I; 118/723 R

(57) ABSTRACT

A chemical vapor deposition (CVD) apparatus and a plasma enhanced chemical vapor deposition (PECVD) apparatus that reduce the number of fine particles inside a chamber. The CVD and the PECVD apparatuses each include a chamber; a gas injection unit that injects a gas into the chamber; a gas exhaust unit that exhausts the gas to the outside of the chamber, and is positioned facing the gas injection unit; a film formation unit that incorporates a film formation region on which a film is formed from the gas, and is positioned between the gas injection unit and the gas exhaust unit; and a electrostatic induction unit, which is positioned around a region corresponding to the film formation region in order not to overlap with the film formation region, and is connected to a voltage source that is insulated from the chamber.

### CROSS-REFERENCE TO RELATED APPLICATIONS

This application claims the benefit of Korean Application No. 2007-53415, filed May 31, 2007 in the Korean Intellectual Property Office, the disclosure of which is incorporated herein by reference.

### BACKGROUND OF THE INVENTION

1. Field of the Invention

Aspects of the present invention relate to chemical vapor deposition (CVD) and plasma enhanced chemical vapor deposition (PECVD) apparatuses, and more particularly, to those in which the number of unwanted fine particles inside of the apparatuses can be reduced.

2. Description of the Related Art

Chemical vapor deposition (CVD) apparatuses are those in which reactive gases are injected into a vacuum chamber, appropriate activity and thermal energy are applied to the gases to induce a chemical reaction, and a desired thin film is thereby formed on the surface of a substrate. CVD apparatuses are used in the formation of thin films for semiconductor devices as well as those in an insulating layer, a metal layer, an organic layer or the like of organic light emitting devices, or liquid crystal display devices that are used in flat display devices. CVD apparatuses are widely used in various industries since the uniformity of the formed thin film is excellent and the growth speed of the coated layer can be freely adjusted. However, CVD apparatuses use high temperature thermal energy as an energy source for the chemical reaction, and thus, problems such as diffusion of deposited atoms, generation of thermal stress during a process, or the like arise.

PECVD apparatuses are those in which injected gases are chemically reacted more effectively by supplying gaseous plasma formed by a collision of electrons having a high energy in order to form a thin film on the surface of a substrate. Because PECVD apparatuses use plasma to facilitate a chemical reaction, the required thermal energy can be significantly reduced. Accordingly, damage to a substrate due to heat can be prevented. Therefore, PECVD apparatuses are also widely used in the formation of thin films for semiconductor devices as well as those in an insulating layer, a metal layer, an organic layer or the like of organic light emitting devices, or liquid crystal display devices that are used in flat display devices.

However, when display devices such as organic light emitting devices, semiconductor devices, or the like have a thin film formed on a substrate using a CVD device or a PECVD device, various fine particles that are generated during the gas reaction step can also be deposited on the substrate inside the chamber of the CVD device or the PECVD device. These fine particles deposited on the substrate deteriorate the quality of the thin film and affect the characteristics of the CVD and PECVD devices.

### SUMMARY OF THE INVENTION

For a CVD apparatus and a PECVD apparatus that include a gas injection unit and a gas exhaust unit that face each other, aspects of the present invention an electrostatic induction unit positioned outside of the film formation region, thereby reducing the number of fine particles inside a chamber of the CVD apparatus and the PECVD apparatus.

One aspect of the present invention provides a chemical vapor deposition (CVD) apparatus comprising: a chamber; a gas injection unit that injects a gas into the chamber; a gas exhaust unit that exhausts the gas to the outside of the chamber and is positioned facing the gas injection unit; a film formation unit that is positioned between the gas injection unit and the gas exhaust unit and incorporates a film formation region on which a film is formed from the gas, ; and an electrostatic induction unit that is positioned around the film formation region in order not to overlap with the film formation region, and is connected to a voltage source that is insulated from the chamber.

The gas injection unit may comprise a gas inlet through which a gas is injected from the outside of the chamber, and a showerhead that is connected to the gas inlet and uniformly disperses the gas into the chamber. The film formation unit may be positioned perpendicular to the direction in which the gas injection unit and the gas exhaust unit face each other. The film formation unit may further comprise a chuck on which a substrate is positioned, and a shadow frame which covers edges of the upper surface of the substrate and is located outside of the film formation region.

The electrostatic induction unit may entirely surround the periphery of the film formation region. Either a positive voltage or a negative voltage is applied to the electrostatic induction unit.

The electrostatic induction unit may instead comprise a first electrostatic induction unit that surrounds one portion of the periphery of the film formation region, and a second electrostatic induction unit that surrounds another portion of the periphery of the film formation region. In the two unit embodiment, a positive voltage may be applied to the first electrostatic induction unit, and accordingly, a negative voltage is applied to the second electrostatic induction unit. Alternatively, a negative voltage may be applied to the first electrostatic induction unit, and accordingly, a positive voltage is applied to the second electrostatic induction unit.

Another aspect of the present invention provides a plasma enhanced chemical vapor deposition (PECVD) apparatus comprising: a chamber; a gas injection unit that injects a gas into the chamber; a gas exhaust unit that exhausts the gas to the outside of the chamber and is positioned facing the gas injection unit; a film formation unit that is positioned between the gas injection unit and the gas exhaust unit and incorporates a film formation region on which a film is formed from the gas, and; a radio frequency (RF) power supply unit that is connected to the gas injection unit to provide high frequency; and an electrostatic induction unit that is positioned around the film formation region in order not to overlap with the film formation region, and is connected to a voltage source that is insulated from the chamber and the RF power supply unit.

The gas injection unit may comprise a gas inlet through which a gas is injected from the outside of the chamber, and a showerhead that is connected to the gas inlet and uniformly disperses the gas into the chamber. The film formation unit may be positioned perpendicular to the direction in which the gas injection unit and the gas exhaust unit face each other. The film formation unit may further comprise a chuck on which a substrate is positioned, and a shadow frame which covers edges of the upper surface of the substrate and is located outside of the film formation region.

The electrostatic induction unit may entirely surround the periphery of the film formation region. Either a positive voltage or a negative voltage is applied to the electrostatic induction unit.

The electrostatic induction unit may instead comprise a first electrostatic induction unit that surrounds one portion of the periphery of the film formation region, and a second electrostatic induction unit that surrounds another portion of the periphery of the film formation region. In the two unit embodiment, a positive voltage may be applied to the first electrostatic induction unit, and accordingly a negative voltage is applied to the second electrostatic induction unit. Alternatively, a negative voltage may be applied to the first electrostatic induction unit, and accordingly, a positive voltage is applied to the second electrostatic induction unit.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become more apparent and more readily appreciated from the following description of the embodiments, taken in conjunction with the accompanying drawings of which:

FIG. 1 is a schematic cross-sectional view of a chemical vapor deposition (CVD) apparatus according to one embodiment of the present invention;

FIG. 2 is a schematic plan view of the CVD apparatus of FIG. 1;

FIG. 3 is a schematic plan view of a CVD apparatus according to another embodiment of the present invention;

FIG. 4 is a schematic cross-sectional view of a plasma enhanced chemical vapor deposition (PECVD) apparatus according to another embodiment of the present invention;

FIG. 5 is a schematic plan view of the PECVD apparatus of FIG. 4; and

FIG. 6 is a schematic plan view of a PECVD apparatus according to another embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

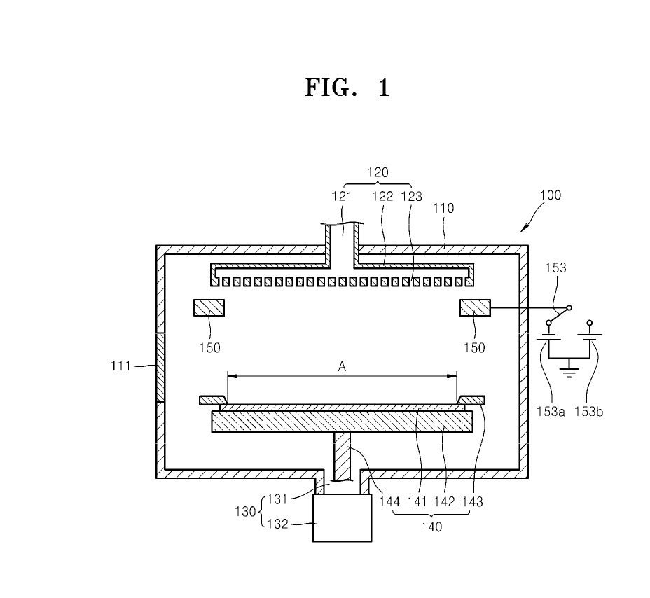

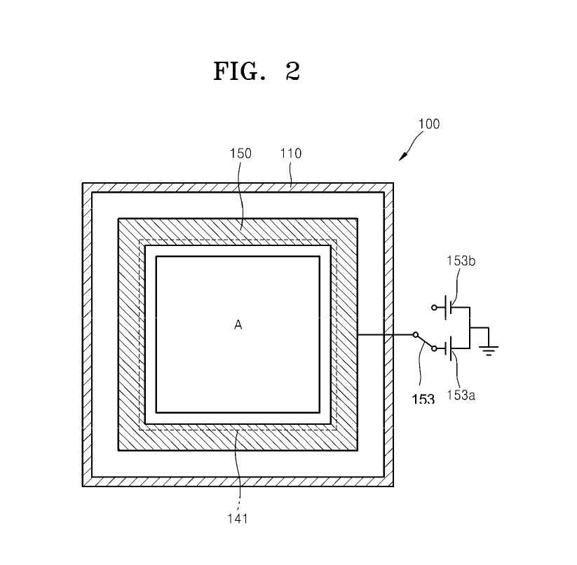

FIG. 1 is a schematic cross-sectional view of a chemical vapor deposition (CVD) apparatus 100 according to an embodiment of the present invention, and FIG. 2 is a schematic plan view of the CVD apparatus of FIG. 1. Referring to FIGS. 1 and 2, the CVD apparatus 100 includes a chamber 110, a gas injection unit 120, a gas exhaust unit 130, a film formation unit 140 and an electrostatic induction unit 150.

The chamber 110 provides a reaction space separated from the external environment. A door 111 through which a transfer device that transfers a substrate into or withdraws a substrate 141 from the chamber 110 is located on one side of the chamber 110. The position and size of the door 111 are not limited to the ones illustrated in FIG. 1.

The gas injection unit 120 is located on an upper portion of the chamber 110, and the gas exhaust unit 130 is located on a lower portion of the chamber 110 facing the gas injection unit 120. The gas injection unit 120 includes a gas inlet 121, and a showerhead 122 connected to the gas inlet 121. Gas involved in a deposition process is injected into the chamber 110 through the gas inlet 121 from the outside of the chamber 110. The injected gas is uniformly sprayed onto a film formation region A through the showerhead 122.

The showerhead 122 includes on its lower surface a plurality of holes 123 that are separated from each other by the same intervals, and the holes 123 uniformly distribute the gas to the film formation region A to improve the uniformity of the thin film that is formed on the substrate 141. However, the showerhead 122 configuration described herein is not limited thereto, and thus, the holes 123 of the showerhead 122 are not necessarily separated from each other by the same intervals, and the showerhead 122 is not necessarily included in the gas injection unit 120.

The gas exhaust unit 130 is located on a lower portion of the chamber 110 facing the gas injection unit 120. The gas exhaust unit 130 includes an exhaust pipe 131, and a vacuum pump 132 that is connected to the exhaust pipe 131 to maintain a predetermined degree of vacuum inside the chamber 110.

As described above, a fine air current from the upper portion of the chamber 110 to the lower portion of the chamber 110 is formed inside the chamber 110 since the gas injection unit 120 and the gas exhaust unit 130 are respectively placed on upper and lower portions of the chamber 110 facing each other. In the current embodiment of the present invention, the gas injection unit 120 and the gas exhaust unit 130 are placed on upper and lower portions of the chamber 110, respectively. However, the present invention is not limited thereto, and the gas injection unit 120 and the gas exhaust unit 130 can be placed in various locations as long as the gas injection unit 120 and the gas exhaust unit 130 face each other. In the present embodiment, the fine air current that is formed inside the chamber 110 can be formed in whichever direction the gas injection unit 120 and the gas exhaust unit 130 face each other.

The film formation unit 140, which includes a chuck 142 on which the substrate 141 is positioned, and a shadow frame 143 are located between the gas injection unit 120 and the gas exhaust unit 130.

The injected gases are reacted together to form the thin film on the substrate 141. In the illustrated embodiment of the present invention, if shadow frames 143 are positioned along end portions of the substrate 141 to guide uniform deposition on the substrate 141, the thin film is formed inside the region outlined by the shadow frames 143, that is, on the film formation region A. The film formation region A, illustrated in FIG. 2, is tetragonal. However, the present invention is not limited thereto and the illustrated film formation region A is only an example. The film formation region A can have various other shapes according to the requirements for the film being formed.

The chuck 142 on which substrate 141 is positioned may further include a heater (not shown) that supplies thermal energy to the substrate 141. In addition, a lifter 144 allows changing the amount of space in which gases are reacted by controlling the amount of space between the gas injection unit 120 and the substrate 141 since the lifter 144 positioned on a lower surface of the chuck 142 can move the substrate 141 in vertical directions.

The film formation unit 140 may be preferably positioned perpendicular to the direction in which the gas injection unit 120 and the gas exhaust unit 130 face each other to guide uniform deposition of the thin film on the substrate 141; however, the present invention is not limited thereto. Since in the current embodiment of the present invention the film formation unit 140 is positioned perpendicular to the direction in which the gas injection unit 120 and the gas exhaust unit 130 face each other, the gas sprayed from the showerhead 122 is uniformly sprayed on the substrate 141. In addition, in order for part of the gas to be deposited on the substrate 141, another part of the gas sprayed on the substrate 141 is involved in a plasma reaction, and that gas that is not deposited on the substrate 141 is exhausted to the outside of the chamber 110 through the exhaust pipe 131 positioned on a lower portion of the chamber 110.

The overall air current inside the chamber 110 flows from the upper portion to the lower portion of the chamber 110. In more detail, the air current inside the chamber 110 flows in the direction from the showerhead 122 to the substrate 141, and in an outer region from the space between the showerhead 122 and the substrate 141, and a fine air current is formed in a direction from the upper portion of the chamber 110 to the exhaust pipe 131 on the lower portion of the chamber 110.

Various fine particles that are generated inside the chamber 110 during the preparation process also flow along with the air current Even though some of the fine particles are exhausted to the outside of the chamber 110 through the exhaust pipe 131, some of the fine particles can be deposited with the reaction gas on the film formation region A, deteriorate the quality of the thin film on the substrate 141 and affect the characteristics of the CVD apparatus.

To prevent the film formation region A from being contaminated by the fine particles as described above, the electrostatic induction unit 150 is positioned between the gas injection unit 120 and the substrate 141.

The electrostatic induction unit 150 is positioned around a region corresponding to the film formation region A between the gas injection unit 120 and the substrate 141 in order not to overlap with the film formation region A, and is connected through a switch 153 to a voltage source 153a or a voltage source 153b that is insulated from the chamber 110.

In the current embodiment of the present invention, for example, a negative voltage 153a is applied to the electrostatic induction unit 150 through a switch 153, and the static induction unit 150 is positioned with a shape which entirely surrounds the peripheries of the region corresponding to the film formation region A. The electrostatic induction unit 150 to which the negative voltage is applied can capture positively-charged fine particles. The positively-charged fine particles can be induced to a position in which the electrostatic induction unit 150 is positioned by the static electrical force of the electrostatic induction unit 150. Since the electrostatic induction unit 150 is positioned outside of the film formation region A, the fine particles induced by the electrostatic induction unit 150 flow to the outside of the film formation region A and then are exhausted to the outside of the chamber 110 through the exhaust pipe 131 with the fine air current formed inside the chamber 110, thereby, resulting in no contamination of the film formation region A.

As another example, a positive voltage can be applied to the electrostatic induction unit 150, through the switch 153 to positive voltage 153b as desired. In this case, for the same reason as described above, negatively-charged fine particles inside the chamber 110 are captured by the electrostatic induction unit 150, or are exhausted to the outside of the chamber 110 by the electrostatic induction unit 150. As a result, the number of fine particles is reduced to prevent contamination of the film formation region A.

As described above, the CVD apparatus 100 includes the electrostatic induction unit 150, which is positioned around a region corresponding to the film formation region A that is between the gas injection unit 120 and the substrate 141, and is connected to the voltage sources 153a or 153b that are insulated from the chamber 110. Therefore, the electrostatic induction unit 150 captures the fine particles inside the chamber 110 or induces the flowing direction of the fine particles to exhaust them to the outside of the chamber 110. As a result, the number of fine particles causing contamination of the film formation region A formed on the substrate 141 can be reduced.

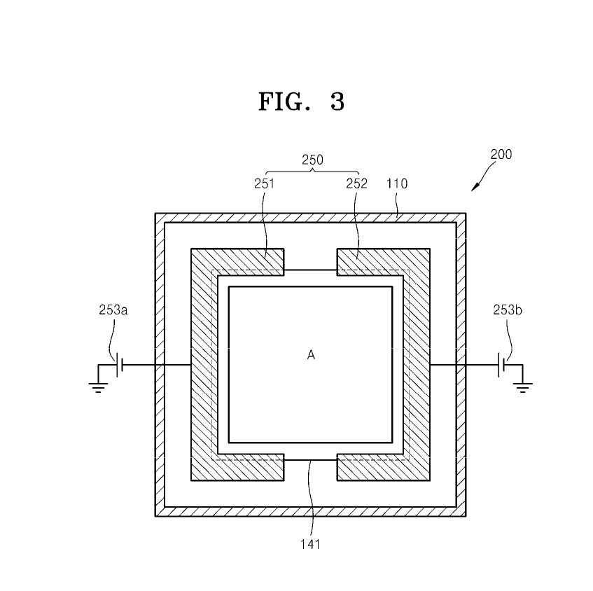

FIG. 3 is a schematic plan view of a CVD apparatus 200 according to another embodiment of the present invention. In the description of the CVD apparatus 200 according to the current embodiment of the present invention, only different aspects of the CVD apparatus 100 according to the previous embodiment of the present invention will be described, and the same aspects of the above-mentioned embodiment will be described with reference to FIG. 1.

Referring to FIG. 3, the CVD apparatus 200 includes the gas injection unit 120, the gas exhaust unit 130, the film formation unit 140 and an electrostatic induction unit 250.

As in the previous embodiment of the present invention, a fine air current is formed in a direction in which the gas injection unit 120 and the gas exhaust unit 130 respectively positioned on an upper and lower portions of the chamber 110 facing each other, that is, from the upper portion of the chamber 110 to the lower portion of the chamber 110.

Referring back to FIG. 1, the film formation unit 140, which includes the substrate 141 and the chuck 142 on which the substrate 141 is positioned, is positioned between the gas injection unit 120 and the gas exhaust unit 130.

Supplied gases are reacted to form a thin film on the substrate 141, and the shadow frames 143 can be positioned on end portions of the substrate 141. In this case, the film formation region A where a film is formed is formed on an inner region of the shadow frame 143.

Gases emitted from the gas injection unit 120 are uniformly sprayed onto the substrate 141, a part of the gases sprayed onto the substrate 141 is involved in a plasma reaction in order for part of the gases to be deposited on the substrate 141, and the gases that are not deposited on the substrate 141 are exhausted to the outside of the chamber 110 through the gas exhaust unit 130 positioned on a lower portion of the chamber 110. The overall air current inside the chamber 110 flows from the upper portion of the chamber 110 to the lower portion thereof, and a fine air current outside of the film formation region A flows towards the exhaust pipe 131 positioned on a lower portion of the chamber 110.

Various fine particles that are generated inside the chamber 110 during the preparation process also flow along with the air current. Even though some of the fine particles are exhausted to the outside of the chamber 110 through the exhaust pipe 131, some of the fine particles can be deposited with the reaction gas on the film formation region. The fine particles deposited on the substrate 141 with the reaction gas deteriorate the quality of the thin film and affect the characteristics of the CVD apparatus.

To prevent the film formation region A from being contaminated by the fine particles described above, the electrostatic induction unit 250 is positioned between the gas injection unit 120 and the substrate 141.

In order not to overlap with the film formation region A, the electrostatic induction unit 250 includes a first electrostatic induction unit 251 that surrounds one portion of the periphery of the region that corresponds to the film formation region A, and a second electrostatic induction unit 252 that surrounds another portion of the periphery of the region that corresponds to the film formation region A.

In the current embodiment of the present invention, the first electrostatic induction unit 251 is connected to a voltage source 253a that is insulated from the chamber 110, and thus, for example, a negative voltage can be applied to the first electrostatic induction unit 251. The second electrostatic induction unit 252 is connected to a voltage source 253b that is insulated from the chamber 110, and thus, for example, a positive voltage can be applied to the second electrostatic induction unit 252. However, the present invention is not limited thereto, and thus, a positive voltage can be applied to the first electrostatic induction unit 251 and a negative voltage can be applied to the second electrostatic induction unit 252.

The first electrostatic induction unit 251 to which a negative voltage is applied can capture positively charged fine particles existing inside the chamber 110. In addition, the positively-charged fine particles can be induced to a position in which the first electrostatic induction unit 251 is positioned using the static electrical force of the first electrostatic induction unit 251. In addition, the second electrostatic induction unit 252 to which a positive voltage is applied can capture negatively charged fine particles, or the negatively charged fine particles can be induced to a position in which the second electrostatic induction unit 252 is positioned using a static electrical force of the second electrostatic induction unit 252.

Since the first electrostatic induction unit 251 and the second electrostatic induction unit 252 are positioned outside of the film formation region A, the fine particles induced by the first and second electrostatic induction units 251 and 252 flow to the outside of the film formation region A to be exhausted to the outside of the chamber 110 through the exhaust pipe 131. Accordingly, the film formation region A is not contaminated.

The first electrostatic induction unit 251 and the second electrostatic induction unit 252 illustrated in FIG. 3 are arranged symmetrical to each other. However, this is only an example, and the present invention is not limited thereto. In addition, the voltage sources 253a and 253b that are connected to the first and second electrostatic induction units 251 and 252, respectively, are not limited to the configuration shown in FIG. 3. In addition, various circuit configurations are possible as long as a constant positive voltage or negative voltage can be applied to each of the first and second electrostatic induction units 251 and 252.

As described above, the CVD apparatus 200 according to the current embodiment of the present invention includes the first electrostatic induction unit 251 to which a positive voltage is applied and the second electrostatic induction unit 252 to which a negative voltage is applied, surrounding the periphery of the region corresponding to the film formation region A, and which are between the gas injection unit 120 and the substrate 141. Accordingly, the first and second electrostatic induction units 251 and 252 capture both positively charged fine particles and negative charged fine particles inside the chamber 110 or the flow direction of the fine particles is induced in order to exhaust the fine particles to the outside of the chamber 110, and thus, the number of fine particles that cause contamination of the film formation region A on the substrate 141 can be efficiently reduced.

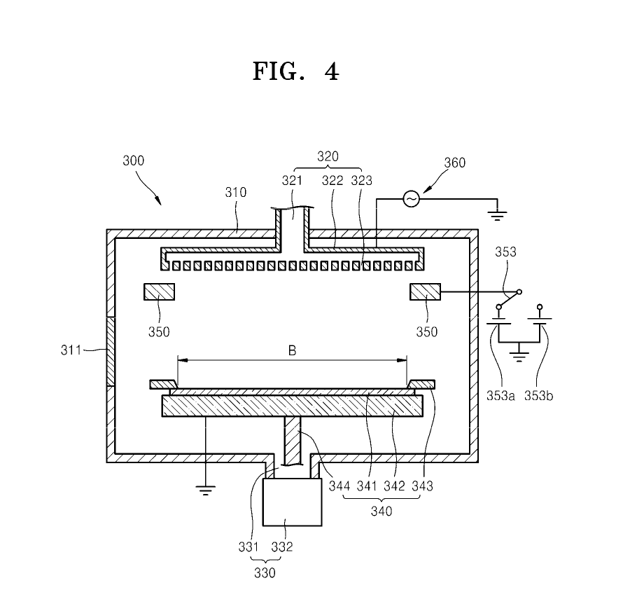

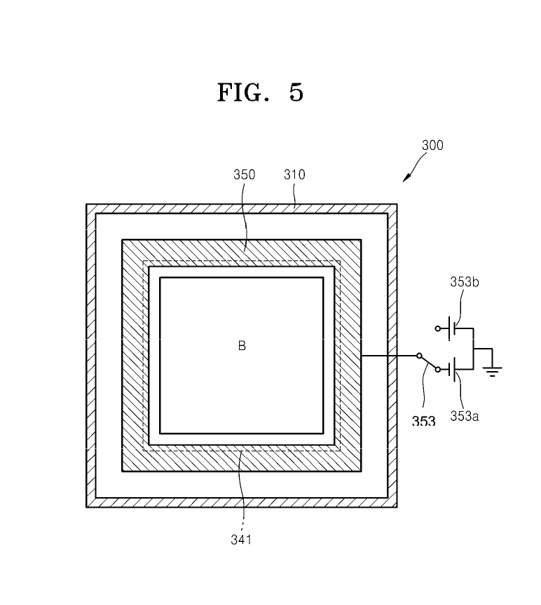

Hereinafter, a plasma enhanced chemical vapor deposition (PECVD) apparatus 300 according to another embodiment of the present invention will be described in more detail with reference to FIGS. 4 and 5. FIG. 4 is a schematic cross-sectional view of a plasma enhanced chemical vapor deposition (PECVD) apparatus 300, according to another embodiment of the present invention, and FIG. 5 is a schematic plan view of the PECVD apparatus 300 of FIG. 4. Referring to FIGS. 4 and 5, the PECVD apparatus 300 includes a chamber 310, a gas injection unit 320, a gas exhaust unit 330, a film formation unit 340, a radio frequency (RF) power supply unit 360 and an electrostatic induction unit 350.

The chamber 310 provides a reaction space separated from the external environment. A door 311 through which a transfer device that transfers a substrate into or withdraws a substrate 341 from the chamber 310 is located on one side of the chamber 310.

The gas injection unit 320 is located on an upper portion of the chamber 310. The gas injection unit 320 includes a gas inlet 321, and a showerhead 322 connected to the gas inlet 321. The showerhead 322 uniformly emits gases injected through the gas inlet 321 into the chamber 310.

The showerhead 322 is connected to the radio frequency (RF) power supply unit 360 that provides an electrical energy in order to bring a reaction gas into a plasma state using a high frequency AC voltage.

The gas exhaust unit 330 is located on a lower portion of the chamber 310 facing the gas injection unit 320. The gas exhaust unit 330 includes an exhaust pipe 331 that exhausts gases inside the chamber 310 to the outside of the chamber 310, and a vacuum pump 332 that is connected to the exhaust pipe 331 to maintain a predetermined degree of vacuum inside the chamber 310.

The film formation unit 340, which includes a chuck 342 on which the substrate 341 is positioned, and a shadow frame 343, is located between the gas injection unit 320 and the gas exhaust unit 330. A ground voltage that grounds radio frequency (RF) power is applied to the chuck 342.

If the temperature of the substrate 341 reaches a predetermined temperature using a heater (not shown), the gases emitted from the showerhead 322 are ionized into a plasma state using RF power in order for the gases to be deposited on the substrate 341. Such a deposition mechanism can be categorized into a first reaction in which a gaseous compound that flows into the chamber 310 is decomposed, a secondary reaction in which the decomposed gaseous ions and unstable radicals interact with each other, and a tertiary reaction in which atoms generated by recombination of the gaseous ions and the radicals interact with each other to generate a nucleus and then form a thin film. The gaseous compound that flows into the chamber varies according to the type of a film that is to be formed. In general, a mixed gas of silane (SiH₄), H₂, NH₃ and N₂ is used in the case of silicon nitride films, SiH₄ and H₂ are used in the formation of amorphous silicon films, and if an amorphous silicon film with an impurity (n+ a-Si) is formed having improved electron mobility by doping phosphorous (P), phosphine (PH₃) is added to the reaction gas used to form the amorphous silicon films.

The gases supplied by the deposition mechanism described above are deposited on a predetermined region of the substrate 341. To prevent plasma discharge and uniformly maintain the deposition thickness of the gases, shadow frames 343 are positioned on end portions of the substrate 341. In this case, a film formation region B on which a thin film is formed is an inner region of the shadow frames 343.

As described above, in the PECVD apparatus 300 according to the current embodiment of the present invention, a fine air current is formed from an upper portion of the chamber 310 to a lower portion of the chamber 310 inside the chamber 310 as a result of the position of the gas injection unit 320 and the gas exhaust unit 330. In addition, if the film formation unit 340 is positioned perpendicular to the direction in which the gas injection unit 320 and the gas exhaust unit 330 face each other, the gas emitted from the showerhead 322 is uniformly sprayed onto the substrate 341. In addition, a part of the gas sprayed onto the substrate 341 is involved in a plasma reaction in order for part of the gas to be deposited on the substrate 341, and the gas that is not deposited on the substrate 341 is exhausted to the outside of the chamber 310 through the gas exhaust unit 330 positioned on a lower portion of the chamber.

In the process of forming a thin film on the substrate 341, various fine particles, such as fine particles generated by the chemical reaction of the reaction gases, fine particles generated when the plasma reaction has finished, or the like, are generated. Such fine particles also flow along with the air current formed inside the chamber 341, and some of the fine particles are exhausted to the outside of the chamber 310 through the exhaust pipe 331. However, some of the fine particles can be deposited with the reaction gases on the film formation region B of the substrate 341, thereby deteriorating the quality of the film and affecting the characteristics of the PECVD apparatus 300.

To prevent the film formation region B from being contaminated by the fine particles, as described above, the electrostatic induction unit 350 is positioned between the gas injection unit 320 and the substrate 341.

The electrostatic induction unit 350 is positioned around a region corresponding to the film formation region B between the gas injection unit 320 and the substrate 341 in order not to overlap with the film formation region B.

In addition, the electrostatic induction unit 350 is connected through a switch 353 to a voltage source 353a or a voltage source 353b that is insulated from the chamber 310 and the RF power supply unit 360. Since the CVD apparatuses 100 and 200 described above do not separately include the RF power supply unit 360, there is no particular limitation on the position of the electrostatic induction unit 150. However, in the PECVD apparatus 300, if the electrostatic induction unit 350 is positioned too close to the showerhead 322, or to the chuck 342 on which the substrate 341 is positioned, there is a possibility of discharge. Therefore, the electrostatic induction unit 350 is positioned so as to maintain a predetermined distance from the showerhead 322 and the chuck 342.

In the current embodiment of the present invention, for example a negative voltage is 353a is applied to the electrostatic induction unit 350 through a switch 353, and the static induction unit 350 is positioned with a shape which entirely surrounds the periphery of the region corresponding to the film formation region B. The electrostatic induction unit 350 to which a negative voltage is applied can capture positively charged fine particles. The positively-charged fine particles can be induced to a position in which the electrostatic induction unit 350 is positioned by means of the electrostatic induction unit 350. Since the electrostatic induction unit 350 is positioned outside of the film formation region B, the fine particles induced by the electrostatic induction unit 350 flow to the outside of the film formation region B and then are exhausted to the outside of the chamber 110 through the exhaust pipe 331 with the fine air current formed inside the chamber 310, thereby resulting in no contamination of the film formation region B.

As another example, a positive voltage can be applied to the electrostatic induction unit 350 as in the CVD 100 according to the previous embodiment of the present invention. In this case, the contamination of the film formation region B can also be prevented.

As described above, the PECVD apparatus 300 according to the current embodiment of the present invention includes the electrostatic induction unit 350, which is positioned around a region corresponding to the film formation region B that is between the gas injection unit 320 and the substrate 341, and is connected through switch 353 to the voltage sources 353a or 353b that are insulated from the chamber 310 and the RF power supply unit 360. Accordingly, the electrostatic induction unit 350 captures fine particles inside the chamber 310 or the flow direction of the fine particles is induced to exhaust the fine particles to the outside of the chamber 310. As a result, the number of fine particles that cause contamination of the film formation region B on the substrate 341 can be efficiently reduced.

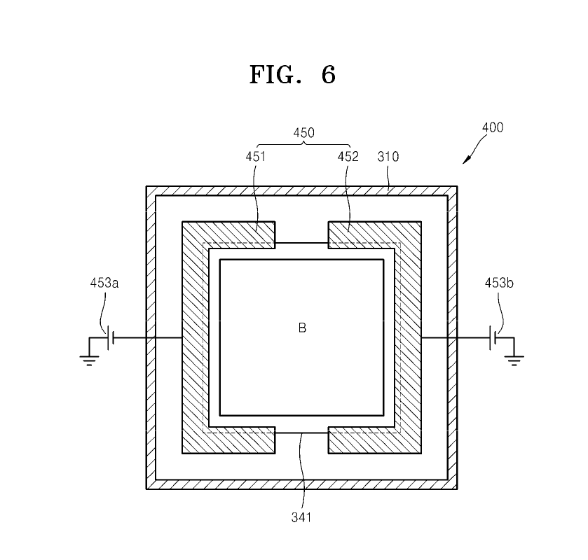

FIG. 6 is a schematic plan view of a PECVD apparatus 400 according to another embodiment of the present invention. In the description of the CVD apparatus 400 according to the current embodiment of the present invention, only different aspects of the PECVD apparatus 300 according to the previous embodiment of the present invention will be described, and the same points aspects of the above-mentioned embodiment will be described with reference to FIG. 4. Referring to FIGS. 4 and 6, the PECVD apparatus 400 includes the chamber 310, the gas injection unit 320, the gas exhaust unit 330, the film formation unit 340, the RF power supply unit 360 and the electrostatic induction unit 450.

If a substrate 341 is heated to a predetermined temperature, gases emitted from the showerhead 322 are ionized into a plasma state in order for the gases to be deposited on the substrate 341. The supplied gases are deposited on a predetermined region of the substrate 341. To prevent plasma discharge and uniformly maintain the deposition thickness, the shadow frames 343 are positioned on end portions of the substrate 341. In this case, a film formation region B on which a film is formed is an inner region of the shadow frames 343.

As described above, in the PECVD apparatus 400 according to the current embodiment of the present invention, a fine air current is formed from an upper portion of the chamber 310 to a lower portion of the chamber 310 inside the chamber 310 as a result of the position of the gas injection unit 320 and the gas exhaust unit 330. In addition, any fine particles that are generated in the process of forming a thin film on the substrate 341 using the plasma process flow along with the fine air current can be deposited on the film formation region B. The fine particles deposited on the substrate 341 with the reaction gas deteriorate the quality of the thin film and affect the characteristics of the device.

To prevent the film formation region B from being contaminated by the fine particles described above, the electrostatic induction unit 450 is positioned between the gas injection unit 320 and the substrate 341. In order not to overlap with the film formation region B, the electrostatic induction unit 450 includes a first electrostatic induction unit 451 that surrounds one portion of the periphery of the region which corresponds to the film formation region B, and a second electrostatic induction unit 452 that surrounds another portion of the periphery of the region that corresponds to the film formation region B.

The first electrostatic induction unit 451 is connected to a voltage source 453a that is insulated from the chamber 310 and the RF power supply unit 360 (not shown), and thus, a negative voltage is applied to the first electrostatic induction unit 451. The second electrostatic induction unit 452 is connected to a voltage source 453b that is insulated from the chamber 310, and thus, a positive voltage is applied to the second electrostatic induction unit 452. However, the present invention is not limited thereto, and a positive voltage can be applied to the first electrostatic induction unit 451 and a negative voltage can be applied to the second electrostatic induction unit 452.

The first electrostatic induction unit 451 to which a negative voltage is applied can capture positively charged fine particles existing inside the chamber 310. In addition, the positively-charged fine particles can be induced to a position in which the first electrostatic induction unit 251 is positioned using the static electrical force of the first electrostatic induction unit 251. In addition, the second electrostatic induction unit 452 to which a positive voltage is applied can capture negatively charged fine particles, or the negatively charged fine particles can be induced to a position in which the second electrostatic induction unit 452 is positioned.

Since the first electrostatic induction unit 451 and the second electrostatic induction unit 452 are positioned outside of the film formation region B, the fine particles induced by the first and second electrostatic induction units 451 and 452 flow to the outside of the film formation region B and then are exhausted to the outside of the chamber 310 through the exhaust pipe 331 along with the fine air current formed inside the chamber 310. Accordingly, the film formation region B is not contaminated.

The first electrostatic induction unit 451 and the second electrostatic induction unit 452 illustrated in FIG. 6 are arranged symmetrical to each other. However, this is only an example, and the present invention is not limited thereto. In addition, the voltage sources 453a and 453b that are connected to the first and second electrostatic induction units 451 and 452, respectively are not limited to the configuration shown in FIG. 6. In addition, various circuit configurations are possible as long as a constant positive voltage or negative voltage can be applied to each of the first and second electrostatic induction units 451 and 452.

As described above, the PECVD apparatus 400 according to the current embodiment of the present invention includes the first electrostatic induction unit 451 to which a positive voltage is applied and the second electrostatic induction unit 452 to which a negative voltage is applied, surrounding portions of the periphery of the region corresponding to the film formation region B, and which are between the gas injection unit 320 and the substrate 341. Accordingly, the first and second electrostatic induction units 451 and 452 respectively capture both positively charged fine particles and negative charged fine particles inside the chamber 310 or the flow direction of the fine particles is induced in order to exhaust the fine particles to the outside of the chamber 110, and thus, the number of fine particles that cause contamination of the film formation region B on the substrate 341 can be efficiently reduced.

A CVD apparatus and A PECVD apparatus according to the present invention can reduce the number of fine particles inside a chamber, and thus, the yield can be improved by forming a thin film of high quality, and the frequency of washing the inside of the chamber can be reduced, thereby resulting in cost reduction and improved production efficiency.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A chemical vapor deposition (CVD) apparatus comprising:
a chamber;
a gas injection unit that injects a gas into the chamber;
a gas exhaust unit that exhausts the gas to the outside of the chamber, and is positioned facing the gas injection unit;
a film formation unit that incorporates a film formation region on which a film is formed from the gas, and is positioned between the gas injection unit and the gas exhaust unit; and
an electrostatic induction unit that is positioned around a region corresponding to the film formation region, and is connected to a voltage source that is insulated from the chamber.

2. The CVD apparatus of claim 1, wherein the gas injection unit comprises a gas inlet through which a gas is injected from the outside of the chamber, and a showerhead that is connected to the gas inlet and uniformly disperses the gas into the chamber.

3. The CVD apparatus of claim 1, wherein the film formation unit is positioned perpendicular to the direction in which the gas injection unit and the gas exhaust unit face each other.

4. The CVD apparatus of claim 1, wherein the film formation unit further comprises a chuck on which a substrate is positioned, and a shadow frame that covers edges of the upper surface of the substrate and is located outside of the film formation region.

5. The CVD apparatus of claim 1, wherein the electrostatic induction unit entirely surrounds the periphery of the region corresponding to the film formation region.

6. The CVD apparatus of claim 5, wherein the voltage applied to the electrostatic induction unit is a positive voltage or a negative voltage.

7. The CVD apparatus of claim 1, wherein the electrostatic induction unit comprises a first electrostatic induction unit that surrounds one portion of the periphery of the region corresponding to the film formation region, and a second electrostatic induction unit that surrounds another portion of the periphery of the region corresponding to the film formation region.

8. The CVD apparatus of claim 7, wherein a positive voltage is applied to the first electrostatic induction unit and a negative voltage is applied to the second electrostatic induction unit.

9. The CVD apparatus of claim 7, wherein a negative voltage is applied to the first electrostatic induction unit and a positive voltage is applied to the second electrostatic induction unit.

10. A plasma enhanced chemical vapor deposition (PECVD) apparatus comprising:
a chamber;
a gas injection unit that injects a gas into the chamber;
a gas exhaust unit that exhausts the gas to the outside of the chamber, and is positioned facing the gas injection unit;
a film formation unit that incorporates a film formation region on which a film is formed from the gas, and is positioned between the gas injection unit and the gas exhaust unit;
a radio frequency (RF) power supply unit that is connected to the gas injection unit to provide high frequency; and
an electrostatic induction unit that is positioned around a region corresponding to the film formation region, and is connected to a voltage source that is insulated from the chamber and the RF power supply unit.

11. The PECVD apparatus of claim 10, wherein the gas injection unit comprises a gas inlet through which a gas is injected from the outside of the chamber, and a showerhead that is connected to the gas inlet and uniformly disperses the gas into the chamber.

12. The PECVD apparatus of claim 10, wherein the film formation unit is positioned perpendicular to the direction in which the gas injection unit and the gas exhaust unit face each other.

13. The PECVD apparatus of claim 10, wherein the film formation unit further comprises a chuck on which a substrate is positioned, and a shadow frame that covers edges of the upper surface of the substrate and is located outside of the film formation region.

14. The PECVD apparatus of claim 10, wherein the electrostatic induction unit entirely surrounds the periphery of the region corresponding to the film formation region.

15. The PECVD apparatus of claim 14, wherein the voltage applied to the electrostatic induction unit is a positive voltage or a negative voltage.

16. The PECVD apparatus of claim 10, wherein the electrostatic induction unit comprises a first electrostatic induction unit that surrounds one portion of the periphery of the region corresponding to the film formation region, and a second electrostatic induction unit that surrounds another portion of the periphery of the region corresponding to the film formation region.

17. The PECVD apparatus of claim 16, wherein a positive voltage is applied to the first electrostatic induction unit and a negative voltage is applied to the second electrostatic induction unit.

18. The PECVD apparatus of claim 16, wherein a negative voltage is applied to the first electrostatic induction unit and a positive voltage is applied to the second electrostatic induction unit.

19. The PECVD apparatus of claim 10, wherein the gas is selected from at least one of the compounds consisting of silane, hydrogen, ammonia, nitrogen, and phosphine.
